(19) United States
(12) Patent Application Publication
(10) Pub. No.: US 2013/0228315 A1
(43) Pub. Date: Sep. 5, 2013

(54) Liquid Coolant Heat Transfer Device

(71) Applicant: James McFarlane Kennedy, Tennyson (AU)

(72) Inventor: James McFarlane Kennedy, Tennyson (AU)

(73) Assignee: Tritium Holdings Pty Ltd., Tennyson (AU)

(21) Appl. No.: 13/885,092

(22) PCT Filed: Nov. 17, 2011
(86) PCT No.: PCT/AU2011/001495

§ 371 Date: May 13, 2013

(30) Foreign Application Priority Data
Nov. 17, 2010 (AU) 2010905094

(51) Int. Cl. H05K 7/20; F28F 13/12

(52) U.S. Cl. CPC H05K 7/20254; F28F 13/12
USPC 165/109.1

(57) ABSTRACT

A liquid coolant heatsink apparatus is provided for cooling devices, such as heat dissipating electronic components. The heat sink apparatus comprises a cooling plate having an outer side for mounting of the device and an inner side formed with a plurality of recesses. A sealing assembly, comprising a base plate and a number of baffles is disposed opposite the inner side of the cooling plate to define a space for circulation of the liquid coolant. The baffles include a plurality of projections which correspond to the recesses and project into them to encourage turbulent flow of the liquid against the inner side of the cooling plate. The baffles are retained in position between the cooling plate and the base plate.

### TECHNICAL FIELD

The present invention relates to a liquid coolant heat transfer device, that is a heatsink. The present invention particularly relates to heatsinks for use with electronic components and devices.

### BACKGROUND

The discussion of any prior art documents, techniques, methods or apparatus is not to be taken to constitute any admission or evidence that such prior art forms, or ever formed, part of the common general knowledge.

Many electronic components dissipate heat during their operation. In order for them to operate effectively it is important that they be prevented from overheating. In particular, semiconductor devices that are used in power electronics circuits, for example power MOSFETs and the like, may need to be kept within a predetermined temperature range if they are to operate efficiently.

In the past a number of approaches have been made to address this problem. For example, extruded aluminum heatsinks, which include a mounting face for the electronic components and a number of heat radiating fins, have been used. However, in order to increase the amount of heat that may be dissipated it has been known to increase the number of fins. Yet, where the gaps between the fins are relatively narrow these devices may become susceptible to “choking” which is a phenomenon wherein air fails to effectively circulate between the fins for purposes of heat transference.

Consequently, in order to provide sufficient heat dissipating surface area without choking occurring this type of heatsink is quite bulky.

Peltier devices are also known for dissipating heat. A Peltier device is a solid state semiconductor device that functions as a heat pump. They are electrically powered, and pump heat from one side of their body to the other. During operation one side gets hotter and the other side gets cooler. Consequently a Peltier effect device can be used to improve cooling of semiconductor devices by fixing the semiconductor to the cool side of the Peltier effect pump, and mounting a passive heatsink on the hot side of the pump. However, Peltier effect devices are expensive, require a passive heatsink and generally require relatively large amounts of power to operate.

It has also been known to use water cooling systems for cooling electronic devices such as microprocessors. These devices typically use metal coils through which a coolant such as water or a water and glycol mixture flows. The coils make contact with a metallic surface for bearing the electronic device. Often fins and in some cases fans are used to assist in cooling the metallic surface in addition to the coils. Obviously this leads to a relatively complex and bulky assembly.

It is an object of the present invention to provide a heat sink apparatus that is relatively straightforward to manufacture and which, in use, presents a low thermal resistance to a device to be cooled.

### SUMMARY OF THE INVENTION

According to a first aspect of the present invention there is provided a heatsink apparatus for a device to be cooled, comprising:
a first plate having an outer side for mounting of the device and an inner side formed with a plurality of recesses;
a sealing assembly opposite the inner side and cooperating therewith to define a space for circulation of a liquid coolant therebetween;
wherein the sealing assembly includes a plurality of projections corresponding to said recesses and projecting therein for turbulent flow of said liquid against the inner side.

The sealing assembly may be formed as a single piece. Alternatively, and preferably, the sealing assembly comprises a closure and a number of baffles comprising the plurality of projections.

In a preferred embodiment the closure comprises a second plate.

The heatsink may include a septum penetrating the space with the recesses disposed on either side thereof wherein the liquid coolant circulates in opposite directions on opposite sides of the septum.

Preferably the baffles comprise pieces of bent sheet metal.

Preferably the baffles are retained between the first plate and the second plate by a clamping or sandwiching action therebetween.

However, where the heatsink apparatus is constructed with a lower precision manufacturing process the baffles may be retained between the first plate and the second plate with some play.

Preferably the inner side includes protrusions abutting portions of the baffles to thereby create passageways between the recesses for circulation of the liquid coolant.

Preferably the baffles have an outer limit flush with a rim of the first plate for supporting the second plate thereon.

According to a further aspect of the present invention, there is provided a heat dissipating electronic device in combination with a liquid coolant heatsink apparatus, comprising:
a cooling plate including an outer side fastened to said electronic device for thermal conduction therewith and an inner side formed with a plurality of recesses;
a closure opposite the inner side and cooperating therewith to define a space for circulation of a liquid coolant therebetween; and
a number of baffles located between the closure and the cooling plate including projections corresponding to said recesses and projecting therein for turbulent flow of said liquid against the inner side.

### BRIEF DESCRIPTION OF THE DRAWINGS

The Detailed Description is not to be regarded as limiting the scope of the preceding Summary of the Invention in any way. The Detailed Description will make reference to a number of drawings as follows:

FIG. 1 is a cross sectional and somewhat stylized view through a heatsink according to a first embodiment of the present invention, in use.

FIG. 2 depicts a heatsink according to a preferred embodiment of the invention in use.

FIG. 3 depicts an exploded view of the underside of the heatsink shown in FIG. 2.

FIG. 4 is a detail of a portion of the view of FIG. 3 showing the baffles displaced from their usual position.

FIG. 5 is a detail of a further portion of the view of FIG. 3 showing the baffles in their usual position.

FIG. 6 is a cross sectional view through the heatsink of FIGS. 2 to 5.

Preferred features, embodiments and variations of the invention may be discerned from the following Detailed Description which provides sufficient information for those skilled in the art to perform the invention.

### DETAILED DESCRIPTION OF PREFERRED EMBODIMENTS

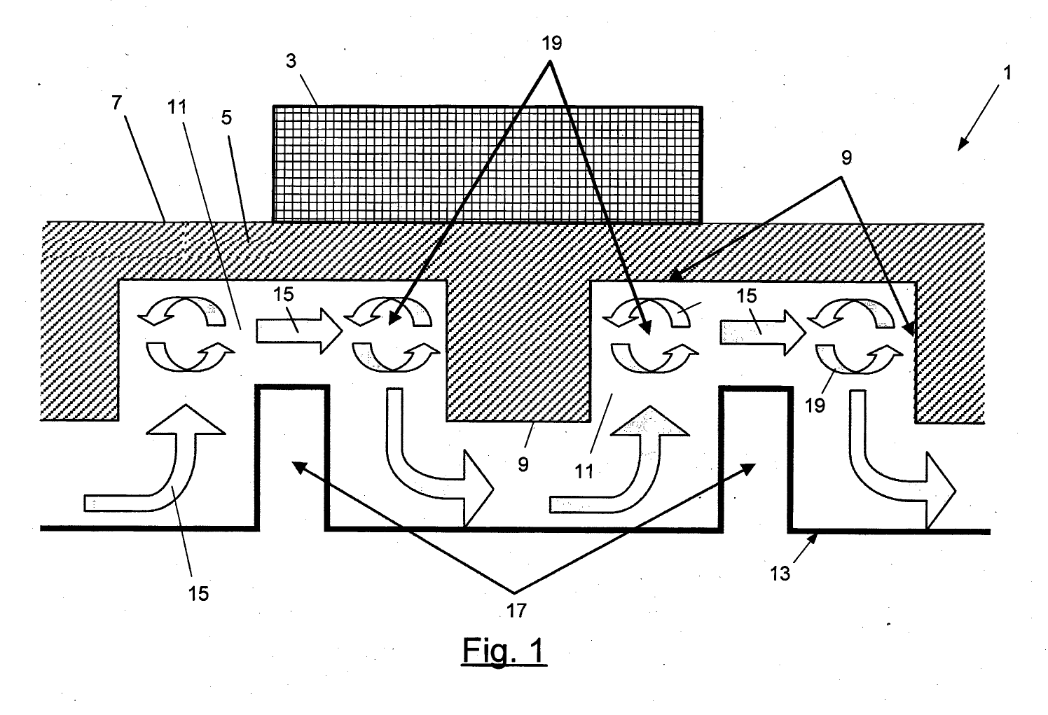

FIG. 1 is a cross sectional, and somewhat schematic view, through a heat sink 1 according to a first embodiment of the invention. The heat sink 1 is shown in use with a device 3 to be cooled attached.

It will be observed that the heat sink 1 comprises a first plate 5, or “cooling plate”, having an outer side 7 for mounting of the device 3 and an inner side 9 formed with a plurality of recesses 11. A sealing assembly 13 is located opposite the inner side 9 of the cooling plate 5. The sealing assembly 13 and the inner side of 9 of the cooling plate 5 cooperatively define a space between them for circulation of a liquid coolant 15 which is pumped through the space during use of the heatsink.

In the presently described embodiment of FIG. 1, the sealing assembly 13 comprises a closure in the form of a sheet of material that is formed with a plurality of projections 17. The projections 17 correspond to the recesses 11 and project into them for encouraging turbulent flow of the liquid 15 against the inner side 9 of the plate 5. The turbulent flow is indicated by the curved arrows 19 in FIG. 1.

The turbulent flow increases the contact time between molecules of the coolant liquid 15 and the inner side 9 of the plate 5 thereby improving heat conductivity from the device 3 to the liquid coolant.

The first plate 5 is a solid material with a high thermal conductivity such as aluminum or copper. The liquid coolant 15 is preferably a water and glycol solution. While it is not important that the sealing assembly 13 has a high thermal conductivity it is preferable that it be made of the same material as the first plate 5 in order to avoid galvanic corrosion.

While rectilinear recesses 11 and projections 17 are shown in FIG. 1, other shapes may also be used, such as curved surfaces, wave shaped surfaces and trapezoidal angled projections. However, whichever shapes are used it is important that they result in turbulent flow of the liquid coolant as it contacts the inner surface 9 of first plate 5.

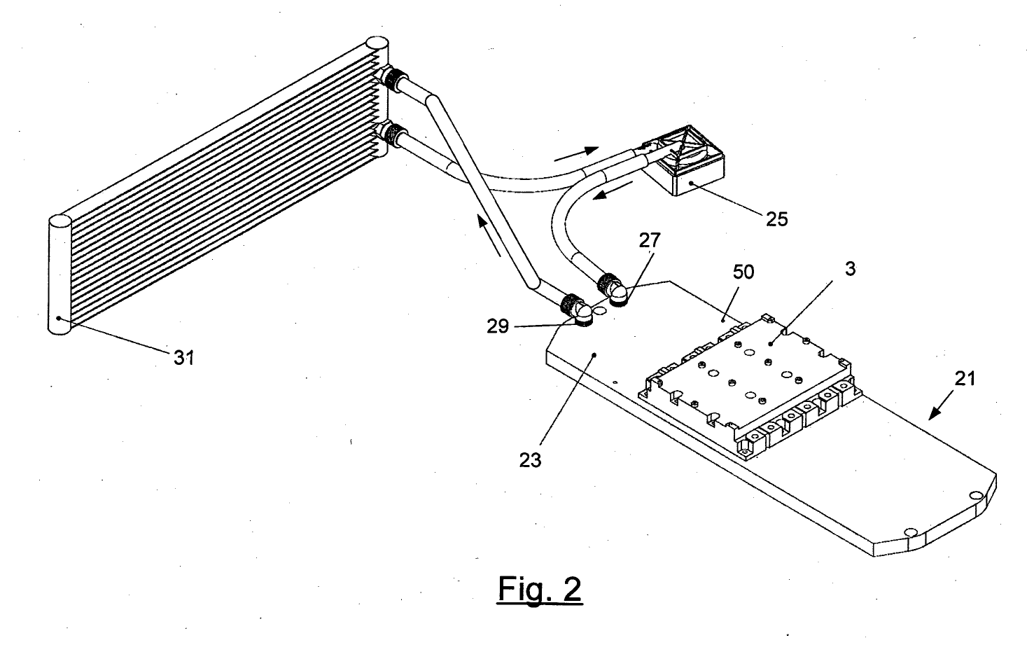

Referring now to FIG. 2, there is shown a heatsink 21 according to a second and preferred embodiment of the present invention, in use. The heatsink 21 has an electronic, heat dissipating device 3 to be cooled mounted to the outer surface of its cooling plate 23. A number of blind threaded holes 50 are provided in the cooling plate to facilitate attachment of devices to be cooled. Other mounting formations, for example pins or posts, may also be provided.

A pump 25 is provided to force liquid coolant into an inlet port 27 of the heatsink 21. As will be described, the liquid coolant circulates within the heatsink 21 and exits via outlet port 29 having received heat from the device 3 during its passage through the heatsink. The coolant then passes through a radiator 31, where it is cooled before being re-circulated again through the heat sink. It will be understood that other components may be introduced into the coolant circuit, for example reservoirs. of coolant or indeed another heat sink might be placed in the coolant circuit depending on requirements and circumstances.

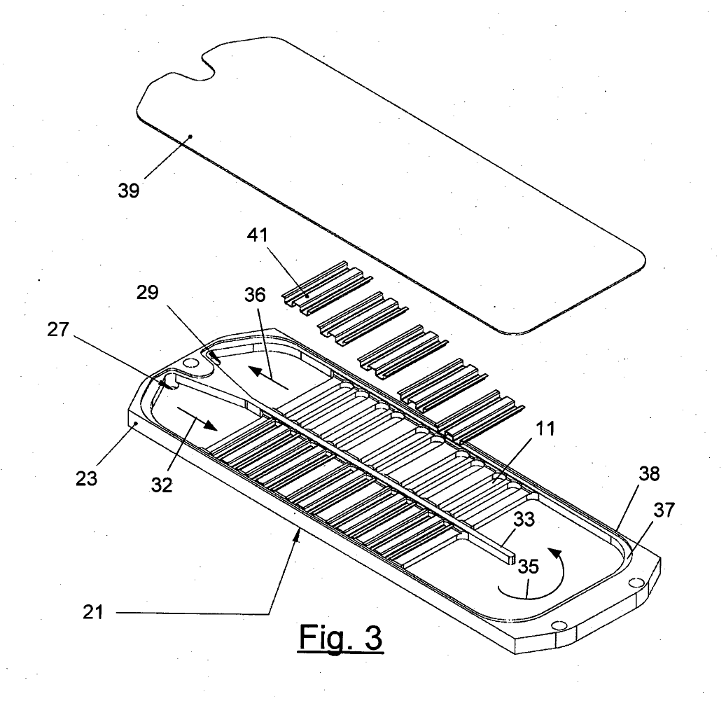

Referring now to FIG. 3, there is shown the underside of the heatsink 21, inverted relative to FIG. 2 and in exploded view. In the following discussion of the arrangement of the heatsink terms such as “topside”, “upper” and “lower” will be made in the context of the heatsink orientated as shown in FIGS. 3 to 6.

It will be observed that the cooling plate 23, which corresponds to cooling plate 5 of FIG. 1, is machined so that a path for the passage of liquid coolant is provided between inlet port 27 and outlet port 29 as indicated by arrows 32, 35 and 36. The path length is effectively doubled by virtue of septum 33 so that in use the coolant is diverted through 180 degrees as indicated by arrow 35. It will be realized that in other embodiments of the invention the septum may be not be present in which case the path of the coolant may comprise a straight line with the inlet and outlet ports disposed at opposite ends of the heatsink.

A peripheral rim 37 is formed around the outside of the plate and bordered by an outer lip 38. The outer edge of a closure in the form of second plate 39, being a base plate for sealing the space within the heatsink 21, rests on peripheral rim 37 snugly within the outer lip 38. As will be explained, the base plate 39 and baffles 41 together comprise a sealing assembly that is functionally similar to sealing assembly 13 of FIG. 1.

While the presently described preferred embodiment has an outer lip 38, other embodiments will not necessarily include the outer lip. Indeed, in some embodiments the closure may not comprise base plate 39 but could instead be another suitable surface, for example even a wall or a bench top.

Referring again to FIG. 3, a plurality of recesses 11 is formed into the inside of the cooling plate 23 on either side of septum 33.

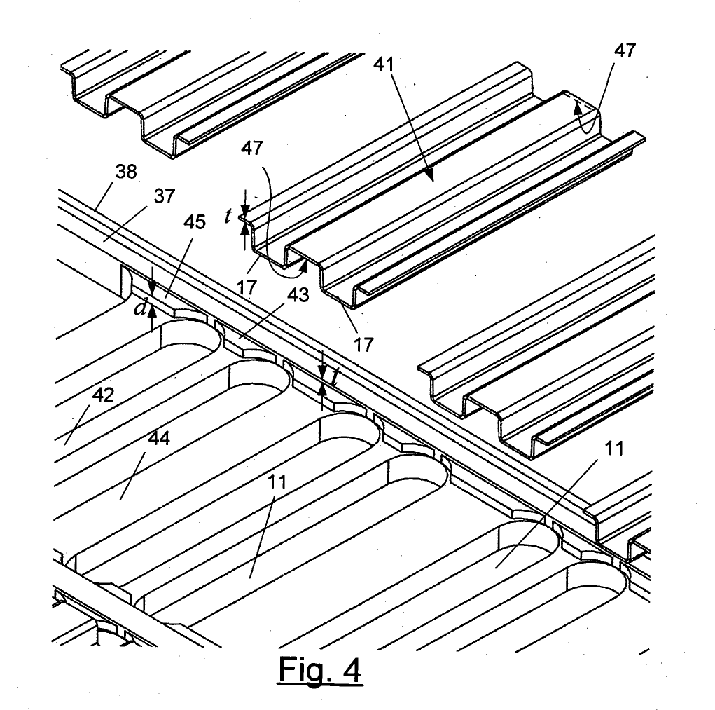

Baffles 41 are sandwiched between base plate 39 and cooling plate 23. The baffles are corrugated with rectilinear projections 17 (indicated in FIG. 4) that extend into the recesses 11. As a result, coolant passing along the path between inlet port 27 and outlet port 29 is forced over the baffle projections and through the recesses in the manner previously described with reference to FIG. 1. Consequently, turbulent flow of the coolant occurs against the inside of cooling plate 23, which improves the heat conductivity from the cooling plate 23 to the liquid coolant.

Referring now to FIG. 4 there is shown a detail exploded view of the baffles 41 and recesses 11. The recesses are separated by narrower and wider wall portions 42 and 44. In the presently described embodiment the baffles are formed of punched sheet metal of thickness “t”. The sheet metal is preferably copper or aluminum, being the same material as the base plate 39 and the cooling plate 23 to avoid galvanic corrosion.

Adjacent opposing ends of the recesses 11 there are formed narrower and wider protrusions in the form of steps 43 and 45 of height “d”. The steps 43 and 45 extend upward at the ends of wall portions 42 and 44

Opposing ends 47 of the undersides of the baffles abut the tops of the steps 43, 45 so that there is a passageway of height d between the underside of the baffles and the top of the walls 42 and 44 through which liquid coolant can proceed. It will again be emphasized that FIGS. 3 and 4 show the heatsink 21 inverted relative to the view provided in FIG. 2.

Accordingly, terms “underside” and “topside” and the like are used here in the context of the views of FIGS. 3 and 4.

The upper limit of steps 43 and 45 is set down a distance t, being the baffle thickness, from the peripheral rim 37 upon which the base plate 39 rests when the heatsink is assembled.

Consequently, in the presently described embodiment the upper extent of the baffles 41 is flush with the rim 37 so that once assembled the baseplate 39 and the steps 43 and 45 sandwich the ends 47 of the baffles to thereby retain them in place. The baseplate 39 is preferably welded, brazed or otherwise fastened to the cooling plate.

While the upper limit of steps 43 and 45 is set down a distance t from the peripheral rim 37 in the presently described embodiment, it could be that it is set down a distance a little greater than t. In that event the baffles would be retained in place though with some play. This possible variation is discussed further later in this specification.

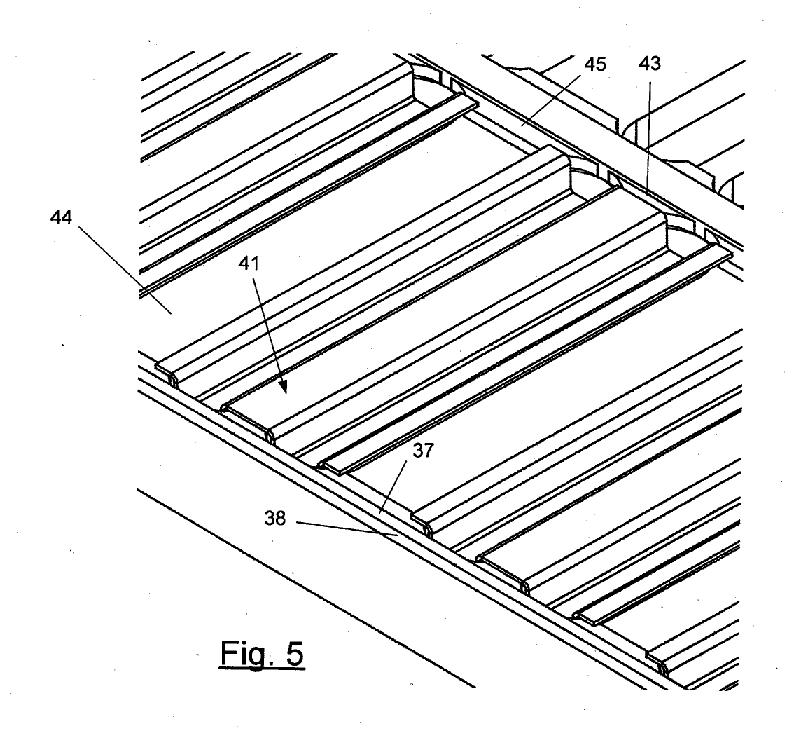

FIG. 5 shows the baffles resting on steps 43 and 45 prior to attachment of the baseplate 39.

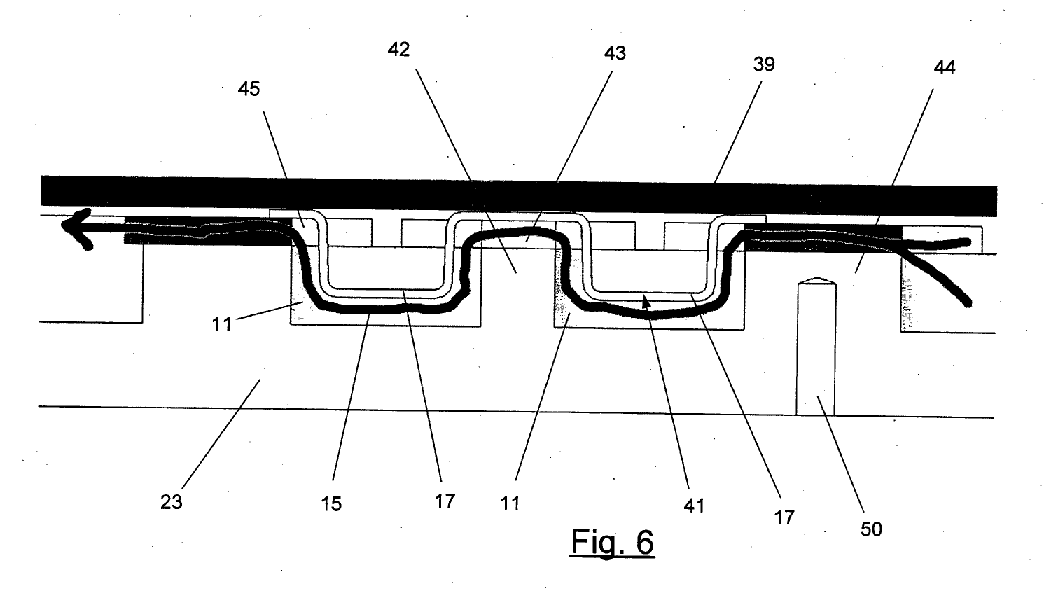

FIG. 6 is a cross sectional view through a baffle of the heatsink of FIGS. 2 to 5 showing the progress of cooling fluid 15 as it circulates over the baffle projections 17 and through the recesses 11.

A heatsink according to the previously described preferred embodiment of FIGS. 2 to 6 enjoys a number of advantages. From a constructional perspective it comprises only one machined part, being cooling plate 23, a plurality of punched metal baffles 41 and the baseplate 39. Machining of the cooling plate 23 is kept to a minimum with only a single large diameter machine tool required to create the recesses and other features such as rim 37 and steps 43 and 45. Consequently, a heatsink according to the preferred embodiment is cost effective to manufacture. Furthermore, the baffles do not have to be individually attached to either the baseplate or the cooling plate since they are retained in place between the two.

An advantage of a heatsink according to some embodiments of the present invention is that, the tolerances and dimensions of the baseplate, baffles and cooling plate do not have to be exact for the heatsink to be effective. It may be that the baseplate does not press against the baffles in some embodiments of the heatsink. In that case the baffles will be retained in the recesses with some play so that they may move a little and rattle if the heatsink is shaken for example. In that case some coolant may circulate between the baffle and the baseplate. However, this is not believed to significantly reduce the effectiveness of the heatsink and allows for embodiments of the heatsink to be cost effectively manufactured. Furthermore, the baffles may extend a little less than the available length of the recesses. Once again, this will mean that a small volume of the coolant will avoid passing between the. recesses and the baffles. However, this is not believed to significantly impair the effectiveness of the heatsink.

The inventor has found that a heatsink according to the preferred embodiment has a liquid thermal resistance of 0.54 Kcm²/W with a flow rate of 6 liters/min. This result is believed to be an improvement over leading heatsinks that are currently commercially available.

In compliance with the statute, the invention has been described in language more or less specific to structural or methodical features. The term “comprises” and its variations, such as “comprising” and “comprised of” is used throughout in an inclusive sense and not to the exclusion of any additional features.

It is to be understood that the invention is not limited to specific features shown or described since the means herein described comprises preferred forms of putting the invention into effect.

The invention is, therefore, claimed in any of its forms or modifications within the proper scope of the appended claims appropriately interpreted by those skilled in the art.

1. A heatsink apparatus for a device to be cooled, comprising:
a first plate having an outer side for mounting of the device and an inner side formed with a plurality of recesses;
a sealing assembly opposite the inner side and cooperating therewith to define a space for circulation of a liquid coolant therebetween;
wherein the sealing assembly includes a plurality of projections corresponding to said recesses and projecting therein for turbulent flow of said liquid against the inner side.

2. A heatsink apparatus according to claim 1 including a septum penetrating the space with the recesses disposed on either side thereof wherein the liquid coolant circulates in opposite directions on opposite sides of the septum in use.

3. A heatsink apparatus according to claim 1, wherein the sealing assembly comprises a closure and a number of baffles comprising the plurality of projections.

4. A heatsink apparatus according to claim 3, wherein the closure comprises a second plate.

5. A heatsink apparatus according to claim 3, wherein the baffles comprise pieces of bent sheet metal.

6. A heatsink apparatus according to claim 3, wherein the baffles are retained between the first plate and the second plate by a clamping or sandwiching action therebetween.

7. A heatsink apparatus according to claim 3, wherein the baffles are retained between the first plate and the second plate with some play.

8. A heatsink apparatus according to claim 3, wherein the inner side includes protrusions abutting portions of the baffles to thereby create passageways between the recesses for circulation of the liquid coolant.

9. A heatsink apparatus according to claim 3, wherein the baffles have an outer limit flush with a rim of the first plate for supporting the second plate thereon.

10. A heatsink apparatus according to claim 1, wherein the first plate comprises a cooling plate machined on the inner side with a single machine tool.

11. A heat dissipating electronic device in combination with a liquid coolant heatsink apparatus, comprising:
a cooling plate including an outer side fastened to said electronic device for thermal conduction therewith and an inner side formed with a plurality of recesses;
a closure opposite the inner side and cooperating therewith to define a space for circulation of a liquid coolant therebetween; and
a number of baffles located between the closure and the cooling plate including projections corresponding to said recesses and projecting therein for turbulent flow of said liquid against the inner side.
